(19) United States
(12) Patent Application Publication
(10) Pub. No.: US 2026/0040842 A1
(43) Pub. Date: Feb. 5, 2026

(54) POST-GAP FILL TREATMENT FOR SEAM REDUCTION

(71) Applicant: Applied Materials, Inc., Santa Clara, CA (US)

(72) Inventors: Sukrant Dhawan, Santa Clara, CA (US); Supriya Ghosh, San Jose, CA (US); Susmit Singha Roy, Campbell, CA (US); Bhaskar Soman, San Jose, CA (US); Akhil Singhal, Portland, OR (US)

(73) Assignee: Applied Materials, Inc., Santa Clara, CA (US)

(21) Appl. No.: 18/790,596

(22) Filed: Jul. 31, 2024

(51) Int. Cl. H01L 21/02

(52) U.S. Cl. CPC H01L 21/0228; H01L 21/02164; H01L 21/02214; H01L 21/02274

(57) ABSTRACT

Exemplary processing methods may include performing a silicon-containing atomic layer deposition (ALD) process. The silicon-containing ALD process may deposit a silicon-containing material in a feature defined in a substrate disposed in a processing region of a semiconductor processing chamber. The methods may include providing an oxygen-containing precursor to a processing region. The methods may include contacting the substrate with the oxygen-containing precursor. The contacting may at least partially reduce a presence of a seam in the silicon-containing material.

### TECHNICAL FIELD

The present technology relates to semiconductor processing. More specifically, the present technology relates to methods of reducing the size of a seam or void in a silicon-containing material.

### BACKGROUND

Integrated circuits are made possible by processes which produce intricately patterned material layers on substrate surfaces. Producing patterned material on a substrate requires controlled methods of formation and removal of exposed material. As device sizes continue to shrink, features within the integrated circuits may get smaller and aspect ratios of structures may grow, and maintaining dimensions of these structures during processing operations may be challenged. Some processing may result in seams or voids in the materials that may result in unwanted and undesirable effects in further processing. Developing materials that can control seam or void formation may become more difficult.

Thus, there is a need for improved systems and methods that can be used to produce high quality devices and structures. These and other needs are addressed by the present technology.

### SUMMARY

Exemplary processing methods may include performing a silicon-containing atomic layer deposition (ALD) process. The silicon-containing ALD process may deposit a silicon-containing material in a feature defined in a substrate disposed in a processing region of a semiconductor processing chamber. The methods may include providing an oxygen-containing precursor to a processing region. The methods may include contacting the substrate with the oxygen-containing precursor. The contacting may at least partially reduce a presence of a seam in the silicon-containing material.

In some embodiments, the silicon-containing ALD process may be plasma-enhanced. The silicon-containing material may be or include a silicon-and-oxygen-containing material. The feature may be characterized by an aspect ratio of greater than or about 2:1. The oxygen-containing precursor may be or include diatomic oxygen (O₂), hydrogen peroxide (H₂O₂), or water or steam (H₂O). The methods may include providing a hydrogen-containing precursor to the processing region with the oxygen-containing precursor. The hydrogen-containing precursor may be or include diatomic hydrogen (H₂). The methods may include forming plasma effluents of the oxygen-containing precursor. Contacting the substrate with the oxygen-containing precursor may form a water or steam (H₂O) by-product. The methods may include repeating performing the silicon-containing ALD process, providing the oxygen-containing precursor, and contacting the substrate with the oxygen-containing precursor for a plurality of cycles.

Some embodiments of the present technology may encompass semiconductor processing methods. The methods may include performing a silicon-containing atomic layer deposition (ALD) process. The silicon-containing ALD process may deposit a silicon-containing material in a feature defined in a substrate disposed in a processing region of a semiconductor processing chamber. A scam or a void may be defined by the silicon-containing material within the feature. The methods may include contacting the substrate with plasma effluents of an oxygen-containing precursor. Contacting the substrate with plasma effluents of the oxygen-containing precursor may cause a size of the seam or the void to be reduced.

In some embodiments, the silicon-containing material may be or include silicon oxide. The plasma effluents of the oxygen-containing precursor may be a microwave plasma effluent or an inductively coupled remote plasma effluent. Contacting the substrate with plasma effluents of an oxygen-containing precursor may cause silicon-containing material from one side of the feature to crosslink with silicon-containing material on an opposite side of the feature. The methods may include providing a hydrogen-containing precursor to the processing region with the oxygen-containing precursor. The methods may include repeating performing the silicon-containing ALD process and contacting the substrate with the plasma effluents of the oxygen-containing precursor for a plurality of cycles. The seam or the void may be a second silicon-containing material characterized by poorer bonding than the silicon-containing material.

Some embodiments of the present technology may encompass semiconductor processing methods. The methods may include performing a silicon-containing atomic layer deposition (ALD) process. The silicon-containing ALD process may deposit a silicon-containing material in a feature defined in a substrate disposed in a processing region of a semiconductor processing chamber. The methods may include providing an oxygen-containing precursor to a processing region. The methods may include contacting the substrate with the oxygen-containing precursor. The contacting may at least partially reduce a presence of a seam in the silicon-containing material. The contacting may be performed at a temperature of greater than or about 400° C.

In some embodiments, the oxygen-containing precursor may be or include steam (H₂O). The substrate may be contacted with the oxygen-containing precursor for a period of time of greater than or about 5 minutes.

Such technology may provide numerous benefits over conventional systems and techniques. For example, by performing a post-gap fill treatment operation, a seam or a void size may be reduced. Additionally, the present technology may produce silicon-containing films for post-deposition applications, as well as any other application for which a reduced seam or void size may be a benefit. By cycling deposition and treatment, a feature may be gap filled with silicon-containing material while reducing or preventing formation of a seam or a void. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

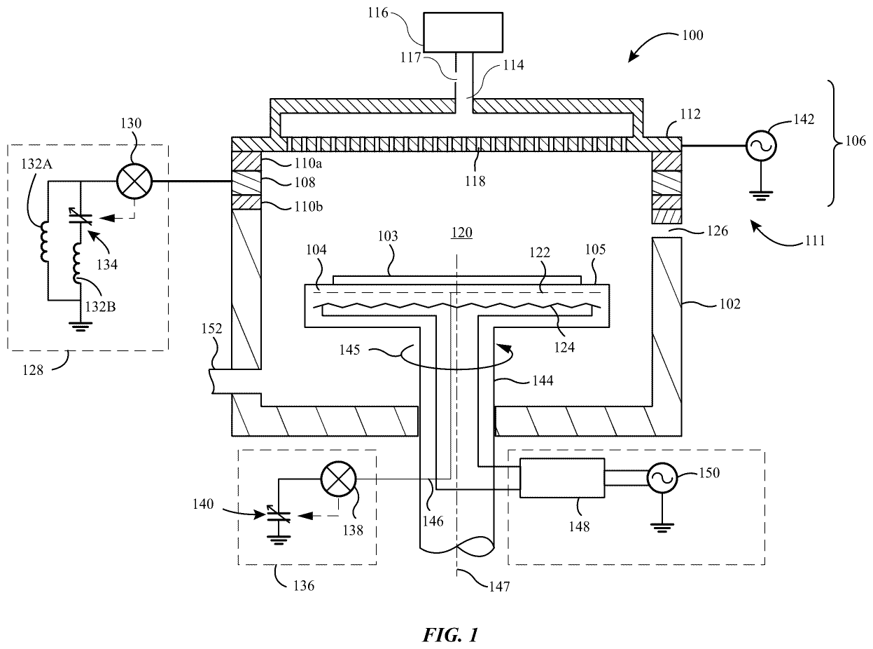

FIG. 1 shows a schematic cross-sectional view of an exemplary processing chamber according to some embodiments of the present technology.

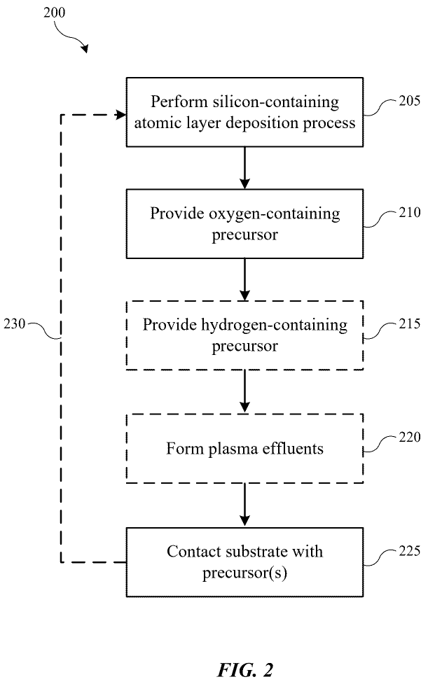

FIG. 2 shows exemplary operations in a processing method according to some embodiments of the present technology.

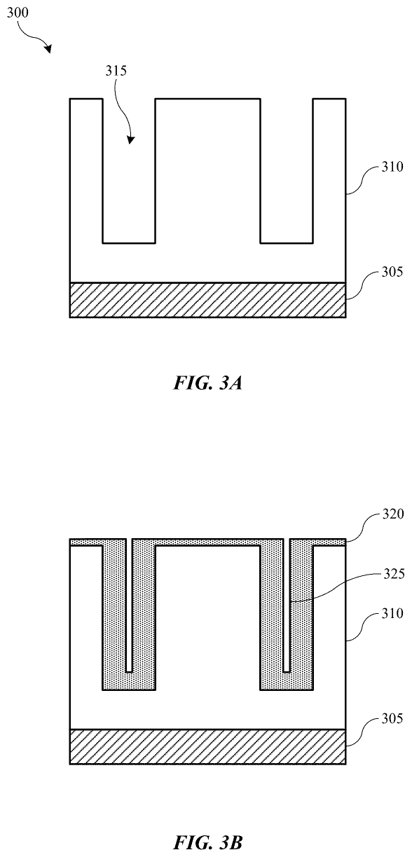

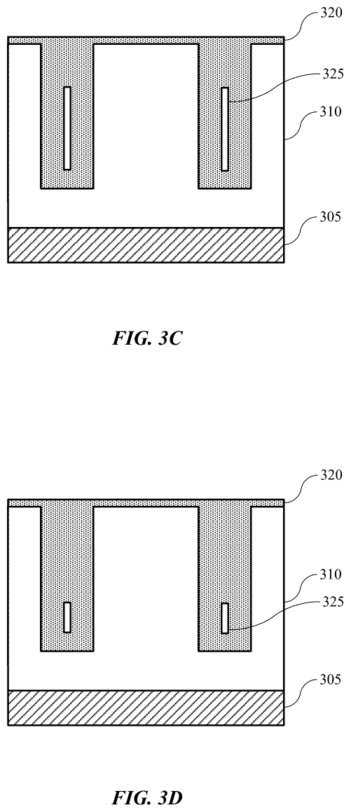

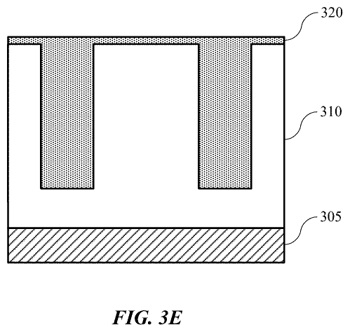

FIGS. 3A-3E show schematic cross-sectional views of a substrate during a processing according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As device sizes continue to shrink, many material layers may be reduced in thickness and size to scale devices. Features inside semiconductor structures may be reduced in size, and aspect ratios of the features may increase. As the aspect ratios of the features increase, atomic layer deposition (ALD) processes may produce seams or voids within the feature.

Conventional technologies have struggled to produce films to fill high aspect ratio features in the underlying structures where seam or void formation is controlled. Deposition of silicon-containing materials on the underlying structures containing the high aspect ratio trenches may be incomplete. The conformal fill operation may allow the feature to seal near the top of the feature prior to fill within the feature, as well as to produce a seam up the middle of the feature, which can extend to the top of the structure. In some production, where a polishing operation may subsequently occur, the removal may cause the seam to be exposed, which may provide access within the feature. This may allow oxidation of the material once exposed to atmosphere, as well as incorporation of slurry or other materials along the seam. Accordingly, many conventional technologies have been limited in the ability to prevent structural flaws in the final devices.

The present technology overcomes these issues by treating a film on the underlying structure to reduce the size of any voids or seams in the film. By treating the film with an oxygen-containing gas or plasma effluents thereof, the present technology may alter the film on the underlying structure to expand the film to effectively narrow the seams or voids or cause the seams or voids to seal or close off at or near an upper portion of the feature. By sealing the features or high aspect ratio structure, the present technology may prevent problems in any following integration processes and/or defects in the final devices.

After describing general aspects of a chamber according to some embodiments of the present technology in which gap filling operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

FIG. 1 shows a cross-sectional view of an exemplary processing chamber 100 according to some embodiments of the present technology. The figure may illustrate an overview of a system incorporating one or more aspects of the present technology, and/or which may perform one or more deposition or other processing operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112, also referred to as a faceplate, and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

Processing chamber 100 may be utilized in some embodiments of the present technology for processing methods that may include gap filling materials for semiconductor structures and post-gap filling treatment to reduce a scam or a void size. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3E, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures on a substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

As illustrated in FIG. 3A, a substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. The substrate 305 may include a material 310 in which one or more features 315 may be formed. Substrate 305 may be any number of materials used in semiconductor processing. The substrate material may be or include silicon, germanium, dielectric materials including silicon oxide or silicon nitride, metal materials, or any number of combinations of these materials, which may be the substrate 305, or materials formed in structure 300. Features 315 may be characterized by any shape or configuration according to the present technology. In some embodiments, the features 315 may be or include a trench structure or aperture formed within the substrate 305 or material 310.

Although the features 315 may be characterized by any shapes or sizes, in some embodiments the features 315 may be characterized by higher aspect ratios, or a ratio of a depth of the feature to a width across the feature. For example, in some embodiments, features 315 may be characterized by aspect ratios greater than or about 1:1, and may be characterized by aspect ratios greater than or about 5:1, greater than or about 10:1, greater than or about 15:1, greater than or about 20:1, greater than or about 30:1, greater than or about 40:1, greater than or about 50:1, greater than or about 60:1, greater than or about 70:1, greater than or about 80:1, greater than or about 90:1, or greater. Additionally, the features may be characterized by narrow widths or diameters across the feature including between two sidewalls, such as a dimension less than or about 100 nm, and may be characterized by a width across the feature of less than or about 90 nm, less than or about 80 nm, less than or about 70 nm, less than or about 60 nm, less than or about 50 nm, less than or about 40 nm, less than or about 30 nm, or less. Further, the features may be characterized by a depth of greater than or about 100 nm, and may be characterized by a depth of greater than or about 250 nm, greater than or about 500 nm, greater than or about 750 nm, greater than or about 1 μm, greater than or about 1.5 μm, greater than or about 2 μm, greater than or about 2.5 μm, greater than or about 3 μm, greater than or about 3.5 μm, greater than or about 4 μm, greater than or about 4.5 μm, greater than or about 5 μm, or more.

Method 200 may include forming gap filling materials for semiconductor structures. However, to reduce or eliminate the presence of a scam or a void in the gap fill material within the feature, which may occur in conventional atomic layer deposition (ALD) or plasma-enhanced ALD (PEALD) processes, method 200 may include a post-gap fill treatment to reduce or eliminate a scam or a void resulting from the ALD or PEALD process. As such, method 200 may include performing a silicon-containing ALD or PEALD process at operation 205 as illustrated in FIG. 3B. The silicon-containing ALD process may deposit a silicon-containing material 320 in the feature 315 defined in the substrate 305 or material 310. As previously discussed, substrate 305 may be disposed in a processing region of a semiconductor processing chamber. The deposition of the silicon-containing material 320 may result in formation of a scam or a void 325. Subsequent to some amount of deposition, and resultant gap fill, method 200 may include providing an oxygen-containing precursor to the processing region at operation 210. At optional operation 215, method 200 may include providing a hydrogen-containing precursor to the processing region. The hydrogen-containing precursor may be provided with the oxygen-containing precursor or separately from the oxygen-containing precursor. In some embodiments, method 200 may include forming plasma effluents at optional operation 220. For example, plasma effluents may be formed of the oxygen-containing precursor and/or, if present, the hydrogen-containing precursor. At operation 225, method 200 may include contacting the substrate with the oxygen-containing precursor and, if present, the hydrogen-containing precursor or plasma effluents thereof. As illustrated in FIG. 3C, the contacting may at least partially reduce a presence of the seam or the void 325 in the silicon-containing material 320. As shown in FIGS. 3D-3E, the contacting may continue for a period of time that may eventually remove the seam or the void 325.

As shown in FIG. 2, the operations of the silicon-containing ALD or PEALD process and the treatment may be repeated at optional operation 230. The operations may be repeated any number of times in cycles to fill features 315 in embodiments of the present technology. While not illustrated, the operations of silicon-containing ALD or PEALD process and the treatment may gradually fill features 315 with silicon-containing material 320 then removing any seam or void 325 prior to continuing to fill the feature with the silicon-containing material 320. For example, the operations may be repeated for a second cycle, a third cycle, a fourth cycle, a fifth cycle, a sixth cycle, a seventh cycle, or any number of cycles, depending on an amount of deposition per cycle and/or aspect ratio/depth of the features 315, necessary to completely fill the features 315 with silicon-containing material 320.

The silicon-containing ALD or PEALD process may include a layer by layer deposition of silicon-containing material 320, which may be a silicon-and-oxygen-containing material. The silicon-containing ALD or PEALD may include a first precursor dose, such as a silicon-containing precursor dose or an oxygen-containing precursor dose. In PEALD processes, plasma effluents of the first precursor dose may be formed. The first precursor dose or, if formed, plasma effluents thereof may be adsorbed, such as through chemisorption, on the substrate 305 or material 310. A first purge may be performed to remove excess amounts of the first precursor dose, such as the first precursor that has not been absorbed on the substrate 305 or material 310.

After the first purge, the silicon-containing ALD or PEALD may include a second precursor dose, such as a silicon-containing precursor dose or an oxygen-containing precursor (the opposite of the first precursor dose). In PEALD processes, plasma effluents of the second precursor dose may be formed. The second precursor or, if formed, plasma effluents thereof may react with the first precursor dose adsorbed on the substrate 305 or material 310. The reaction between the first precursor dose and the second precursor dose may form the silicon-containing material 320. A second purge may be performed to remove excess amounts of the second precursor dose, such as the second precursor that has not reacted with the first precursor to form silicon-containing material 320.

Although any silicon-containing precursor may be used, in some embodiments, the silicon-containing precursor(s) may be used during the silicon-containing ALD or PEALD process may include, but are not limited to, silane (SiH₄), disilane (Si₂H₆), trisilane (Si₃H₈), tetrasilane (Si₄H₁₀), pentasilane (SisH₁₂), or other organosilanes including cyclohexasilanes, an aminosilane, silicon tetrafluoride (SiF₄), silicon tetrachloride (SiCl₄), dichlorosilane (SiH₂Cl₂), tetraethyl orthosilicate (TEOS), as well as any other silicon-containing materials that may be used or useful in semiconductor processing. Similarly, although any oxygen-containing precursor may be used, in some embodiments, the oxygen-containing precursor(s) may be used during the silicon-containing ALD or PEALD process may include, but are not limited to, diatomic oxygen (O₂), nitrous oxide (N₂O), hydrogen peroxide (H₂O₂), or other oxygen-containing materials that may be used or useful in semiconductor processing.

If plasma-enhanced, a plasma power source may deliver a plasma power to the faceplate, chamber, or substrate support of greater than or about 250 W, and may deliver a power of greater than or about 500 W, greater than or about 1,000 W, greater than or about 1,500 W, greater than or about 2,000 W, greater than or about 2,500 W, greater than or about 3,000 W, greater than or about 3,500 W, greater than or about 4,000 W, greater than or about 4,500 W, greater than or about 5,000 W, greater than or about 5,500 W, greater than or about 6,000 W, greater than or about 7,000 W, greater than or about 8,000 W, or more.

After the second purge, the first precursor dose, first purge, and second precursor dose, and second purge may be repeated any number of times to continue forming silicon-containing material 320. The deposition may be conformal, and thus, growth may occur inward within the feature 315 from the walls defining the feature 315. The ALD or PEALD process may be performed for a period of time sufficient to produce an amount of coverage to at least partially fill the feature 315. As the feature 315 closes, a scam or a void 325, which may be a void as illustrated a distance within the feature, may be formed. The scam or void 325 may extend a portion or all of a distance of the feature 315 to an exposed upper surface as illustrated. Although illustrated as a consistent opening, it is to be understood that scam or void 325 may be characterized by a number of shapes, which may include top-wide, bottom wide, as well as a more amorphous shape, as would be readily understood by the skilled artisan. To reduce or prevent the formation of the seam or the void 325, method 200 may include a post-gap fill treatment at operation 210-225. It is also contemplated that method 200 may include intermittently performing the treatment of operations 210-225.

Temperature may impact operations of the present technology. For example, the ALD or PEALD process may be performed at a temperature less than or about 600° C., and may be performed at a temperature less than or about less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., or less. Additionally, the method 200 may be performed at a temperature greater than or about 100° C., and may be performed at a temperature greater than or about 300° C., and may be performed at a temperature greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., or more. The temperature may be maintained in any of these ranges throughout the ALD or PEALD process.

Pressure may also impact operations of the present technology. For example, the ALD or PEALD process may be performed at a pressure less than or about 50 Torr, and may be performed at a pressure less than or about 40 Torr, less than or about 30 Torr, less than or about 20 Torr, less than or about 15 Torr, less than or about 10 Torr, less than or about 8 Torr, less than or about 6 Torr, less than or about 5 Torr, less than or about 4 Torr, less than or about 3 Torr, less than or about 2 Torr, less than or about 1 Torr, or less.

The oxygen-containing precursor provided at operation 210 may be or include O₂, H₂O₂, water or steam (H₂O), or any other oxygen-containing precursor used or useful in semiconductor processing. If provided, the hydrogen-containing precursor provided at optional operation 215 may be or include diatomic hydrogen (H₂), H₂O₂, H₂O, or any other hydrogen-containing precursor used or useful in semiconductor processing. The oxygen-containing precursor and, if present, the hydrogen-containing precursor may be provided with one or more diluents or carrier gases such as an inert gas or other gas delivered with the poisoning precursor.

While thermal treatments may still ensure seam or void reduction at locations within the features 315, a plasma-enhanced treatment may allow thermal budgets to be protected, while also increasing the penetration of seam or void reduction within the feature, which may improve the depth at which the seam may be sealed. In embodiments in which the treatment is plasma-enhanced, a plasma power may impact the depth of hydrogen penetration, the extent of bond reorientation, and the amount of seam sealing that may occur. Accordingly, in some embodiments the plasma power may be greater than or about 50 W, and may be greater than or about 100 W, greater than or about 200 W, greater than or about 300 W, greater than or about 400 W, greater than or about 500 W, greater than or about 600 W, greater than or about 700 W, greater than or about 800 W, greater than or about 900 W, greater than or about 1,000 W, greater than or about 1,250 W, greater than or about 1,500 W, greater than or about 1,750 W, greater than or about 2,000 W, greater than or about 3,000 W, greater than or about 4,000 W, greater than or about 5,000 W, greater than or about 6,000 W, greater than or about 7,000 W, greater than or about 8,000 W, or more. However, at higher plasma power the bombardment may cause sputtering or etching of the silicon-containing material 320 or material 310, and thus in some embodiments the plasma power may be less than or about 8,000 W, less than or about 7,000 W, less than or about 6,000 W, less than or about 5,000 W, less than or about 4,000 W, less than or about 3,000 W, less than or about 2,000 W, less than or about 1,500 W, less than or about 1,250 W, less than or about 1,000 W, or less.

Various plasma formation methods may be used to form plasma effluents of the oxygen-containing precursor and, if present, the hydrogen-containing precursor. Some embodiments may include forming a remote plasma, such as an inductively-coupled remote plasma, of the oxygen-containing precursor and, if present, the hydrogen-containing precursor. After forming remote plasma effluents, the plasma effluents may be provided to the processing region. As such, the plasma effluents of the oxygen-containing precursor and, if present, the hydrogen-containing precursor may be an inductively coupled remote plasma effluent. Other embodiments may include forming a microwave plasma. As such, the plasma effluents of the oxygen-containing precursor and, if present, the hydrogen-containing precursor may be a microwave plasma effluent. While other plasma formation methods are possible, remote plasma formation and microwave plasma formation may produce radical dominant plasmas. The radical dominant plasmas may have a reduced possibility of ion-related damage. The radical dominant plasmas may be characterized by deeper penetration as the lifetime of radicals may be longer than ions.

Whether thermal or plasma-enhanced, at operation 225, the silicon-containing material 320 and the oxygen-containing precursor and, if present, the hydrogen-containing precursor or plasma effluents thereof may be reacted within the processing region, which may alter the silicon-containing material 320 on the substrate 305. As illustrated in FIGS. 3C-3E, the silicon-containing material 320 on the substrate 305 may be hydrogenated and expand to an increased volume, which may result in decreased density, when treated with the oxygen-containing precursor and, if present, the hydrogen-containing precursor or plasma effluents thereof. The oxygen and, if present, hydrogen may be pulling terminal hydrogen out of the silicon-containing material 320 proximate the seam or void 325, which may cause the silicon-containing material 320 from one side of the feature 315 to crosslink with the silicon-containing material 320 on an opposite side of the feature 315. As such, the treatment may increase SiOSi crosslinking in the silicon-containing material 320 proximate the seam or void 325. For example, and without being bound to any particular theory, the seam or void 325 may be formed at least in part from terminated surfaces in the silicon-containing material 320 growing from either side of the feature 315. It is also contemplated that the seam or void 325 may be silicon-containing material, such as a second silicon-containing material characterized by poorer bonding than the silicon-containing material 320. The oxygen and, if present, hydrogen may increase bond breaking and restructuring, which may allow silicon and oxygen chains to form across the regions, and allow the seam or void 325 to be sealed. This may cause a size of the scam or void 325 to be reduced as shown, which may ensure that the seam or void 325 is not exposed in subsequent processing. With the bond breaking and restructuring, contacting the substrate 305 with the oxygen-containing precursor and, if present, the hydrogen-containing precursor or plasma effluents thereof may form a H₂O by-product.

To increase an amount of the treatment, such as a depth of the seam or void 325 that is sealed, the substrate 305 may be contacted with the oxygen-containing precursor and, if present, the hydrogen-containing precursor or plasma effluents thereof for a period of time of greater than or about 5 minutes, such as greater than or about 10 minutes, greater than or about 20 minutes, greater than or about 30 minutes, greater than or about 40 minutes, greater than or about 50 minutes, greater than or about 1 hour, or more.

Although a portion of the seam or void 325 may remain after treatment with the oxygen-containing precursor and, if present, the hydrogen-containing precursor or plasma effluents thereof, in some embodiments of the present technology, the seam or void 325 may be substantially reduced or fully closed at or near an upper surface of the silicon-containing material 320. For example, from an entrance of the feature, the seam may be fully resolved or sealed to a depth of greater than or about 1% of the depth of the feature, and may be sealed to a depth of greater than or about 5% of the depth of the feature, greater than or about 10% of the depth of the feature, greater than or about 20% of the depth of the feature, greater than or about 30% of the depth of the feature, greater than or about 40% of the depth of the feature, greater than or about 50% of the depth of the feature, or more.

Temperature may be adjusted during the post-gap fill treatment or may be maintained at the temperature of the ALD or PEALD process. However, higher temperatures may increase effectiveness of treating or healing the seam or void 325, such as during a thermal anneal treatment. As such, embodiments may include increasing the temperature from a first temperature during the ALD or PEALD process at operation 205 to a second temperature during the post-gap fill treatment at operations 210-225. As such, the post-gap fill treatment at operations 210-225 may be performed at a temperature of greater than or about 150° C., greater than or about 200° C., greater than or about 250° C., greater than or about 300° C., greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., or more. However, the temperature may be limited by a thermal budget of one or more materials or structures on the substrate 305. As such, the post-gap fill treatment at operations 210-225 may be performed at a temperature of less than or about 750° C., and may be performed at a temperature less than or about less than or about 700° C., less than or about 650° C., less than or about 600° C., less than or about 550° C., less than or about 500° C., less than or about 475° C., less than or about 450° C., less than or about 425° C., less than or about 400° C., less than or about 375° C., less than or about 350° C., less than or about 325° C., less than or about 300° C., less than or about 250° C., less than or about 200° C., less than or about 150° C., less than or about 100° C., or less. The temperature may be maintained in any of these ranges throughout the post-gap fill treatment at operations 210-225. However, it is also contemplated that the temperature may be adjusted between operations.

Pressure may be maintained during the ALD or PEALD process at operation 205 and the post-gap fill treatment at operations 210-225. Adjusting pressure may reduce throughput and, therefore, increase queue times. However, it is contemplated that some embodiments may include adjusting the pressure from a first pressure during the ALD or PEALD process at operation 205 to a second pressure that may be higher or lower than the first pressure during the post-gap fill treatment at operations 210-225. For example, the post-gap fill treatment at operations 210-225 may be performed at a pressure less than or about 100 Torr, and may be performed at a pressure less than or about 90 Torr, less than or about 80 Torr, less than or about 70 Torr, less than or about 60 Torr, less than or about 50 Torr, less than or about 40 Torr, less than or about 30 Torr, less than or about 20 Torr, less than or about 15 Torr, less than or about 10 Torr, less than or about 8 Torr, less than or about 6 Torr, less than or about 5 Torr, less than or about 4 Torr, less than or about 3 Torr, less than or about 2 Torr, less than or about 1 Torr, or less. Additionally, the post-gap fill treatment at operations 210-225 may be performed at a pressure greater than or about 1 Torr, and may be performed at a pressure greater than or about 2 Torr, greater than or about 3 Torr, greater than or about 4 Torr, greater than or about 5 Torr, greater than or about 6 Torr, greater than or about 8 Torr, greater than or about 10 Torr, greater than or about 15 Torr, greater than or about 20 Torr, greater than or about 30 Torr, greater than or about 40 Torr, greater than or about 50 Torr, greater than or about 60 Torr, greater than or about 70 Torr, greater than or about 80 Torr, greater than or about 90 Torr, greater than or about 100 Torr, or more. Higher pressures may increase the amount or the depth of the seam that is treated and sealed.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an oxygen-containing precursor” includes a plurality of such precursors, and reference to “the silicon-containing material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
performing a silicon-containing atomic layer deposition (ALD) process, wherein the silicon-containing ALD process deposits a silicon-containing material in a feature defined in a substrate disposed in a processing region of a semiconductor processing chamber;
providing an oxygen-containing precursor to the processing region; and
contacting the substrate with the oxygen-containing precursor, wherein the 6 contacting at least partially reduces a presence of a seam in the silicon-containing material.

2. The semiconductor processing method of claim 1, wherein the silicon-containing ALD process is plasma-enhanced.

3. The semiconductor processing method of claim 1, wherein the silicon-containing material comprises a silicon-and-oxygen-containing material.

4. The semiconductor processing method of claim 1, wherein the feature is characterized by an aspect ratio of greater than or about 2:1.

5. The semiconductor processing method of claim 1, wherein the oxygen-containing precursor comprises diatomic oxygen (O₂), hydrogen peroxide (H₂O₂), or water or steam (H₂O).

6. The semiconductor processing method of claim 1, further comprising:
providing a hydrogen-containing precursor to the processing region with the oxygen-containing precursor.

7. The semiconductor processing method of claim 1, wherein the hydrogen-containing precursor comprises diatomic hydrogen (H₂).

8. The semiconductor processing method of claim 1, further comprising:
forming plasma effluents of the oxygen-containing precursor.

9. The semiconductor processing method of claim 1, wherein contacting the substrate with the oxygen-containing precursor forms a water or steam (H₂O) by-product.

10. The semiconductor processing method of claim 1, further comprising:
repeating performing the silicon-containing ALD process, providing the oxygen-containing precursor, and contacting the substrate with the oxygen-containing precursor for a plurality of cycles.

11. A semiconductor processing method comprising:
performing a silicon-containing atomic layer deposition (ALD) process, wherein the silicon-containing ALD process deposits a silicon-containing material in a feature defined in a substrate disposed in a processing region of a semiconductor processing chamber, wherein a 4 seam or a void is defined by the silicon-containing material within the feature; and
contacting the substrate with plasma effluents of an oxygen-containing precursor, wherein contacting the substrate with the plasma effluents of the oxygen-containing precursor cause a size of the seam or the void to be reduced.

12. The semiconductor processing method of claim 11, wherein the silicon-containing material comprises silicon oxide.

13. The semiconductor processing method of claim 11, wherein the plasma effluents of the oxygen-containing precursor are a microwave plasma effluent or an inductively coupled remote plasma effluent.

14. The semiconductor processing method of claim 11, wherein contacting the substrate with plasma effluents of an oxygen-containing precursor causes silicon-containing material from one side of the feature to crosslink with silicon-containing material on an opposite side of the feature.

15. The semiconductor processing method of claim 11, further comprising:
providing a hydrogen-containing precursor to the processing region with the oxygen-containing precursor.

16. The semiconductor processing method of claim 11, further comprising:
repeating performing the silicon-containing ALD process and contacting the 2 substrate with the plasma effluents of the oxygen-containing precursor for a plurality of cycles.

17. The semiconductor processing method of claim 11, wherein the seam or the void is a second silicon-containing material characterized by poorer bonding than the silicon-containing material.

18. A semiconductor processing method comprising:
performing a silicon-containing atomic layer deposition (ALD) process, wherein the silicon-containing ALD process deposits a silicon-containing material in a feature defined in a substrate disposed in a processing region of a semiconductor processing chamber;
providing an oxygen-containing precursor to a processing region; and
contacting the substrate with the oxygen-containing precursor, wherein the contacting at least partially reduces a presence of a seam in the silicon-containing material, and wherein the contacting is performed at a temperature of greater than or about 400° C.

19. The semiconductor processing method of claim 18, wherein the oxygen-containing precursor comprises steam (H₂O).

20. The semiconductor processing method of claim 18, wherein the substrate is contacted with the oxygen-containing precursor for a period of time of greater than or about 5 minutes.
